(19) United States
(12) Patent Application Publication
(10) Pub. No.: US 2025/0212415 A1
(43) Pub. Date: Jun. 26, 2025

(54) FERROELECTRIC STORAGE DEVICE AND METHOD FOR MANUFACTURING SUCH A DEVICE

(71) Applicant: COMMISSARIAT A L'ENERGIE ATOMIQUE ET AUX ENERGIES ALTERNATIVES, PARIS (FR)

(72) Inventors: Julien BORREL, GRENOBLE CEDEX 09 (FR); Justine BARBOT, GRENOBLE CEDEX 09 (FR); Jean COIGNUS, GRENOBLE CEDEX 09 (FR); Laurent GRENOUILLET, GRENOBLE CEDEX 09 (FR)

(21) Appl. No.: 18/990,572

(22) Filed: Dec. 20, 2024

(30) Foreign Application Priority Data
Dec. 21, 2023 (FR) 2314880

(51) Int. Cl. H10B 51/20

(52) U.S. Cl. CPC H10B 51/20

(57) ABSTRACT

A method for manufacturing a ferroelectric storage device includes depositing a first layer, depositing a first layer of ferroelectric material, depositing an intermediate layer onto the first layer of ferroelectric material, removing a first part of the intermediate layer so as to expose a part of the first layer of ferroelectric material, depositing a second layer of ferroelectric material onto the intermediate layer and onto the part exposed of the first layer of ferroelectric material, removing a second part of the intermediate layer so as to form a layer of ferroelectric material including a first part of a first thickness and a second part of a second thickness, the first and second thicknesses being distinct, depositing a second layer, the layer of ferroelectric material extending between the first layer and the second layer.

### CROSS-REFERENCE TO RELATED APPLICATIONS

This application claims priority to French Patent Application No. 2314880, filed Dec. 21, 2023, the entire content of which is incorporated herein by reference in its entirety.

### FIELD

The present invention generally relates to the field of microelectronics. It relates more particularly to the field of non-volatile memories.

In particular, the invention relates to a ferroelectric storage device. It also relates to a method for manufacturing such a ferroelectric storage device.

### BACKGROUND

The main quality of FeRAM (Ferroelectric Random Access Memory)-type ferroelectric memories is that they are non-volatile, i.e. they retain the information stored even when the voltage is turned off. They also have the advantage of consuming little energy and having low write and read times relative to other types of non-volatile memory such as FLASH memory.

Ferroelectric memories of the FeRAM type generally take the form of a stack in which a layer of ferroelectric material is positioned between two metal electrodes.

Ferroelectric memories are capacitive type memories with two remanent polarisation states, +Pr and −Pr. The operation of these ferroelectric memories is based on the ferroelectric properties of the ferroelectric material placed between two metal electrodes.

More particularly, as regards the operation of FeRAM type ferroelectric memories, by the application of a potential difference between the two electrodes creating an electric field having a value greater than a positive coercive field +Ec, the ferroelectric memory is placed in a high remanent polarisation state +Pr and by the application of a potential difference creating an electric field having a value less than the negative coercive field −Ec, the ferroelectric memory is placed in a low remanent polarisation state −Pr.

The high remanent polarisation state +Pr then corresponds to the binary logic state ‘0’ and the low remanent polarisation state −Pr to the binary logic state ‘1’, which allows information to be stored.

Furthermore, when the application of the potential difference between the two metal electrodes is stopped, the remanent polarisation state remains: this explains the non-volatile nature of ferroelectric memories.

For reading, it is assumed that the memory is in a given state and a voltage is applied. This voltage is for example positive, greater than the voltage creating an electric field with a value greater than the positive coercive field +Ec. Thus, if the memory was already in the high remanent polarisation state +Pr, this polarisation state is unchanged and no current spike is observed (or a very small current spike may be observed). Conversely, if the memory was in the low remanent polarisation state −Pr, a much larger current peak is observed.

The consequence of this read operation is that it destroys the polarisation state.

Ferroelectric Tunnel Junction (FTJ) memories are also known. FTJ-type ferroelectric memories generally take the form of a stack in which a layer of ferroelectric material is positioned between two metal electrodes. FTJ ferroelectric memories are resistive type memories with two opposite polarisation states for the layer of ferroelectric material. The operation of these ferroelectric memories is based on ferroelectric properties of the ferroelectric material placed between two metal electrodes.

More particularly, as regards the operation of FTJ-type ferroelectric memories, the two polarisation states respectively correspond to two different resistance levels: a high-resistance level, corresponding for example to a high polarisation state +Pr, and a low-resistance level, corresponding to a low polarisation state −Pr. By way of example, the low-resistance level has an electrical resistance approximately one thousand times lower than that of the high-resistance level.

In the case of FTJ-type ferroelectric memories, the read operation comprises the application of a read voltage −Vr. The read voltage −Vr is, for example, negative and lower in absolute value than a voltage Vc associated with the coercive field. This enables non-destructive reading to be carried out by measuring a tunnel current.

In order to increase memory density, it is known to implement a so-called “multi-level” storage. This “multi-level” storage is associated with different polarisation states, on which it will be possible to store information.

Document “Multilevel data storage memory using deterministic polarization control.” by Lee, Daesu et al. in Advanced materials, vol. 24(3), 2012, 402-406, doi: 10.1002/adma.201103679 describes a FeRAM-type ferroelectric memory with several storage levels. In this example, as is represented in FIG. 1 (representing the course of the polarisation P as a function of the applied voltage V), the memory can be placed in several intermediate remanent polarisation states Pr₁, Pr₂, Pr₃, Pr₄, Pr₅, Pr₆, Pr₇ (Pr₀ corresponding to the state 0 of low polarisation). It will therefore be possible to store information at different levels. Thanks to this “multi-level” storage, it is possible to code several states per memory (here, in the example, eight states are coded), whereas in a standard cell only two states are accessible (states 0 or 1 only). Thus, the information contained in a memory with “multi-level” storage is equivalent to that contained in several standard memories.

In practice, in this example, to implement this storage on the different intermediate levels, each intermediate polarisation state Pr₁, Pr₂, Pr₃, Pr₄, Pr₅, Pr₆, Pr₇ is associated with a corresponding current. Thus, upon application of a voltage between the electrodes, an associated ferroelectric current is read. This current then makes it possible to identify the intermediate polarisation state Pr₁, Pr₂, Pr₃, Pr₄, Pr₅, Pr₆, Pr₇ concerned and therefore to deduce the information initially stored in this intermediate polarisation state Pr₁, Pr₂, Pr₃, Pr₄, Pr₅, Pr₆, Pr₇ of the ferroelectric memory.

However, some drawbacks are observed in such high-density memories. For example, it can be difficult to distinguish between two intermediate polarisation states that are close to each other. Indeed, an overlap between the different intermediate polarisation states may be encountered. In such a case, the application of a voltage (between the electrodes) to this overlap zone does not allow the associated current, and therefore the intermediate remanent polarisation state associated therewith, to be deduced with some certainty.

### SUMMARY

The present invention therefore aims to improve high-density ferroelectric storage devices by allowing unambiguous distinction between different polarisation states.

One or more aspects of the invention then relate to a method for manufacturing a ferroelectric storage device comprising the steps of:
providing a support layer,
depositing a first layer,
depositing a first layer of ferroelectric material, and then
depositing an intermediate layer onto the first layer of ferroelectric material, and then
removing a first part of the intermediate layer so as to expose a part of the first layer of ferroelectric material, and then
depositing a second layer of ferroelectric material onto the intermediate layer and onto the part exposed of the first layer of ferroelectric material, and then
removing a second part of the intermediate layer so as to form, from the first layer of ferroelectric material and a portion of the second layer of ferroelectric material, a layer of ferroelectric material comprising a first part having a first thickness and a second part having a second thickness, the first thickness and the second thickness being distinct, and
depositing a second layer, the layer of ferroelectric material extending between the first layer and the second layer.

Thus, according to the manufacturing method in accordance with an aspect of the invention, the layer of ferroelectric material in the ferroelectric storage device according to an aspect of the invention has a non-uniform thickness. This variability in thickness leads to non-uniformity in the ferroelectric properties of the ferroelectric storage device. This non-uniformity of properties especially makes it possible to increase differences between the voltage ranges to be applied to store information in the different intermediate polarisation states.

Indeed, the different thicknesses mean that, for a given (write) voltage, the electric field is greater in regions of lower thickness. In other words, to write information in an intermediate polarisation state associated with a low thickness, a higher voltage has to be applied. The differences in thickness therefore lead to differences in the voltages to be applied to encode information in the different intermediate polarisation states.

The different thicknesses used are therefore associated with different intermediate polarisation states in the ferroelectric storage device.

In other words, by virtue of the non-uniformity created in the layer of ferroelectric material (due to thickness variability), differences between the intermediate polarisation states are created.

Further to the characteristics just discussed in the preceding paragraphs, the method for manufacturing ferroelectric storage device according to one aspect of the invention may have one or more additional characteristics from among the following, considered individually or according to any technically possible combinations:
depositing the first layer of ferroelectric material is conformally implemented;
   depositing the intermediate layer is conformally implemented;
the intermediate layer comprises a nitride or an oxide;
the step of removing the first part of the intermediate layer is implemented by anisotropic etching;
depositing the second layer of ferroelectric material is conformally implemented;
the step of removing the second part of the intermediate layer is implemented by isotropic etching;
the layer of ferroelectric material comprises hafnium dioxide or hafnium dioxide doped with a doping element or an alloy HfₓZr₁₋ₓO₂, with 0<x<1; and
there is provided, prior to the step of depositing the first layer, a step of forming a cavity in the support layer, the cavity comprising a bottom wall and a side wall, the side wall forming a tilt angle relative to a direction normal to the bottom wall, depositing the first layer, the layer of ferroelectric material and the second layer being implemented in the cavity formed,
   the second part of the layer of ferroelectric material being positioned on the bottom wall of the cavity and the first part of the layer of ferroelectric material being positioned on the side wall of the cavity.

One or more aspects of the invention also relate to a ferroelectric storage device comprising: a first layer, a second layer and a layer of ferroelectric material which extends between the first layer and the second layer,
the ferroelectric storage device comprising a support layer which comprises a cavity, the cavity comprising a bottom wall and a side wall, the side wall forming a tilt angle relative to a direction normal to the bottom wall,
the first layer, the layer of ferroelectric material and the second layer being located in the cavity,
the layer of ferroelectric material comprising a first part having a first thickness and a second part having a second thickness, the first thickness and the second thickness being distinct, the first part and the second part of the layer of ferroelectric material being positioned between the first layer and the second layer,
the second part of the layer of ferroelectric material comprising a first portion extending as an extension of the first part and a second portion extending as a projection from the first portion of the second part of the layer of ferroelectric material, the second portion being arranged such that a free end of the second portion is positioned closer to the second layer than to the first layer.

### BRIEF DESCRIPTION OF THE FIGURES

Further characteristics and benefits of the invention will become clearer from the description thereof given below, by way of indicating and in no way limiting purposes, with reference to the appended figures, wherein:

FIG. 1 illustrates the different intermediate polarisation states in operation in the case of a FeRAM-type ferroelectric memory with several storage levels,

FIG. 2 schematically represents an example of a ferroelectric storage device in accordance with the invention,

FIG. 3 represents, in the form of a flow chart, an example of the method for manufacturing the ferroelectric storage device of FIG. 2,

FIG. 4 illustrates step E102 of the manufacturing method represented in FIG. 3,

FIG. 5 illustrates step E104 of the manufacturing method represented in FIG. 3,

FIG. 6 illustrates step E106 of the manufacturing method represented in FIG. 3,

FIG. 7 illustrates step E108 of the manufacturing method represented in FIG. 3,

FIG. 8 illustrates step E110 of the manufacturing method represented in FIG. 3,

FIG. 9 illustrates step E112 of the manufacturing method represented in FIG. 3,

FIG. 10 illustrates step E114 of the manufacturing method represented in FIG. 3, and

FIG. 11 illustrates step E116 of the manufacturing method represented in FIG. 3,

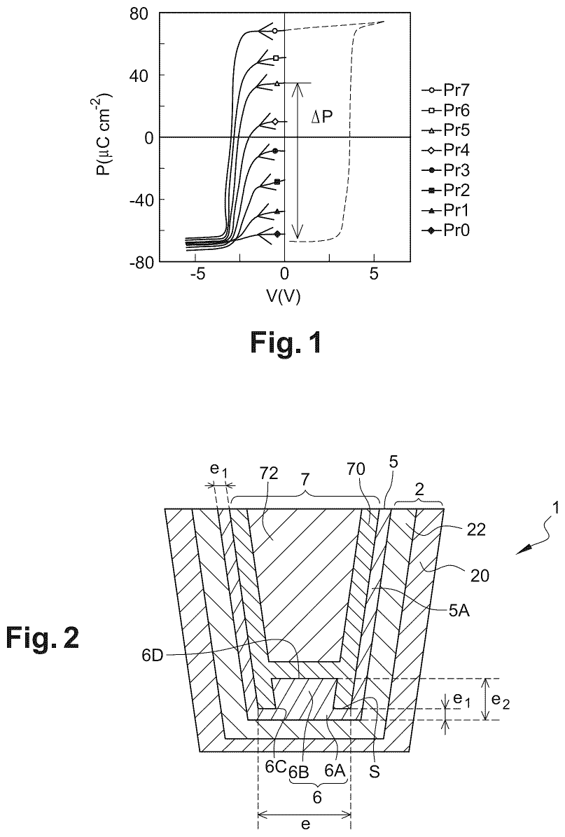

For greater clarity, identical or similar elements are identified by identical reference signs throughout the figures.

### DETAILED DESCRIPTION

The present invention aims to improve the manufacture of ferroelectric storage devices. In particular, the present invention relates to a high-density storage device wherein several polarisation states are used to store information. The present invention then aims to improve the definition of the polarisation states so as to be able to clearly distinguish between them in order to then be able to read the stored piece of information associated with each of the polarisation states.

FIG. 2 represents a ferroelectric storage device 1 in accordance with an embodiment of the invention. As is visible in this figure, the ferroelectric storage device 1 comprises a first layer 2, a second layer 7 and a layer of ferroelectric material 5 which is disposed between the first layer 2 and the second layer 7.

The ferroelectric storage device 100 is in the form of a stack of layers. The first layer 2, the layer of ferroelectric material 5 and the second layer 7 form the different layers of this stack.

As will be described in more detail later, along with the manufacturing method associated, the ferroelectric storage device 1 is formed in a cavity 50 (visible in FIGS. 4 to 11).

This cavity 50 is for example formed in a support layer 10. In other words, the cavity 50 forms a part of the support layer 10 which has an overall “U”-shaped profile (as will be seen later, the side limbs of the “U”-shape are here tilted relative to the base of the “U”-shape). Here, the different layers of the ferroelectric storage device 1 have a similar shape profile to the cavity 50 with a “U”-shaped profile of the support layer 10.

This support layer 10 is for example formed of a dielectric material. For example, the support layer 10 comprises silicon oxide SiO₂.

The support layer may comprise a plurality of sub-layers. For example, the support layer may comprise another layer of dielectric material formed beneath the layer comprising silicon oxide SiO₂. This other layer comprises, for example, silicon nitride SiN or silicon carbonitride SiCN.

The cavity 50 comprises a bottom wall 52 and a side wall 55. The bottom wall 52 corresponds to the base of the “U” shape and the side wall 55 corresponds to the side limbs of the “U” shape. The side wall 55 forms a tilt angle α relative to an axis z, corresponding to a direction normal to the bottom wall 52. In an embodiment, this tilt angle α is non-zero. Alternatively, this tilt angle may be zero (the side wall is therefore vertical).

The stack forming the ferroelectric storage device 1 extends from the bottom wall 52 and the side wall 55. This stack then comprises several parts (one extending from the bottom wall 52) and another extending from the side wall 55. For the part formed on the bottom wall 52, the different layers of the stack extend in parallel to each other. The same applies to the part extending from the side wall 55 (the different layers of the stack also extend in parallel to each other on this side wall 55).

Alternatively, the side wall of the cavity could comprise a plurality of portions forming distinct angles relative to a direction normal to the bottom wall. In other words, the side wall of the cavity could have a plurality of breaks of slope.

Each of the layers forming the ferroelectric storage device 1 is now described.

The first layer 2 is made of an inert conductive material. This first layer 2 comprises, for example, a metal material.

According to a first example (not represented), the first layer comprises a single layer. The conductive material of this single layer comprises, for example, titanium nitride TiN. Alternatively, the conductive material may be tantalum nitride TaN or tungsten W. Still alternatively, other conductive materials may be used (and in particular metal nitride more generally).

As is visible in the example represented in FIG. 2, the first layer 2 is in the form of a two-layer structure. It comprises herein a first sub-layer 20 and a second sub-layer 22.

The second sub-layer 22 is disposed on the first sub-layer 20.

The first sub-layer 20 comprises a metal conductive material. In an embodiment, it comprises titanium Ti or tantalum nitride TaN.

The first sub-layer 20 has a thickness of between 3 and 20 nanometres (nm). In an embodiment, this thickness is between 5 and 10 nm.

This first sub-layer 20 acts both as a protective layer and as a contact layer for electrically connecting the device 1 to its electronic control and read circuit.

The second sub-layer 22 is disposed on the first sub-layer 20. It is in direct contact with the layer of ferroelectric material 5. In other words, the second sub-layer 22 extends between the first sub-layer 20 and the layer of ferroelectric material 5.

The second sub-layer 22 is formed of a conductive material comprising a transition metal. This conductive material is, for example, titanium nitride TiN. Alternatively, it may be other conductive materials such as tantalum Ta or tungsten W.

For example, when the second sub-layer 22 comprises titanium nitride, the first sub-layer 20 is formed of a conductive material such as titanium Ti.

Alternatively, when the second sub-layer 22 comprises tantalum, the first sub-layer 20 is formed, for example, of tantalum nitride TaN.

Still alternatively, when the second sub-layer 22 comprises tungsten, the first sub-layer 20 is formed of a conductive material of titanium Ti.

Herein, the thickness of the second sub-layer 22 is between 10 and 100 nm. In an embodiment, this thickness is between 5 and 10 nm.

Alternatively, the first layer may comprise a semiconductor material. This semiconductor material comprises silicon, for example.

The layer of ferroelectric material 5 is disposed on the first layer 2.

Alternatively, the layer of ferroelectric material can be deposited onto another layer previously formed on the first layer.

This layer of ferroelectric material 5 comprises an active material having variable resistance. This layer of ferroelectric material 5 is based, for example, on hafnium dioxide HfO₂. In the present description, by the term “based on”, it is meant that the layer concerned comprises more than 50% of the element mentioned after this term (for example herein, this means that the layer of ferroelectric material 5 comprises more than 50% hafnium dioxide).

Alternatively, hafnium dioxide can be doped with a doping element. In the present description, the expression “doping” of a layer relates to the introduction into the material of the layer concerned of atoms of another material referred to as a “doping element”.

Here, in an embodiment, the used doping element is silicon Si. In the case of silicon, the layer of ferroelectric material based on hafnium dioxide is for example exposed to a dose of dopant of between 1.1014 cm⁻² and 1.1015 cm⁻² in order to obtain a presence of between 0.7 and 7% of silicon atoms in the layer of ferroelectric material. In an embodiment, the dose of dopant is between 0.3.1015 cm⁻² and 1.1015 cm⁻².

Alternatively, other doping elements can be used, such as aluminium Al, germanium Ge, gadolinium Gd, yttrium Y, lanthanum La, scandium Sc or nitrogen N.

Still alternatively, the layer of ferroelectric material may comprise an alloy of the form HfₓZr₁₋ₓO₂, where 0<x<1. For example, it is possible to use a ternary HfZrO₂ alloy (for example Hf_{0.5}Zr_{0.5}O₂) as the ferroelectric material. Still alternatively, the layer of ferroelectric material can be made of aluminium scandium nitride (AlScN).

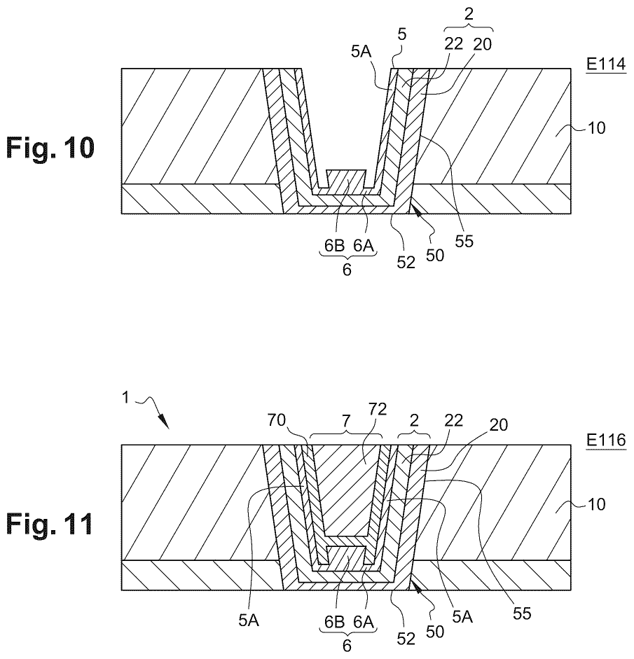

As is visible in FIG. 2, the layer of ferroelectric material 5 comprises at least a first part 5A and a second part 6. Herein (visible in FIG. 10), the first part 5A extends at the side wall 55 of the cavity 50 while the second part 6 extends at the bottom wall 52 of the cavity 50.

Beneficially, according to an embodiment of the invention, the first part 5A has a first thickness e₁ and the second part 6 has a second thickness e₂. In the present invention, the thickness of a part of a layer is defined as the distance separating the two faces of the part of the layer concerned. In other words, the thickness corresponds to the characteristic dimension of the layer concerned in a direction parallel to a direction normal to the faces of the part of the layer concerned.

Here, the first thickness e₁ and the second thickness e₂ are distinct. In other words, the layer of ferroelectric material 5 has a non-uniform thickness. In other words, the layer of ferroelectric material 5 has a variable thickness.

Differences in thickness are essential characteristics of the ferroelectric storage device for obtaining different polarisation states.

Thus, by virtue of various embodiments of the invention, the different thicknesses used for the layer of ferroelectric material introduce a non-uniformity in the ferroelectric properties of the layer of ferroelectric material. This non-uniformity of properties especially makes it possible to increase differences between the voltage ranges to be applied to encode the information in the different intermediate polarisation states. This makes it possible to avoid overlapping between the voltage ranges concerned and therefore to unambiguously identify the intermediate polarisation states related to the stored information.

In order to obtain very distinct polarisation states (i.e. with no overlap between the ranges of voltages to be applied to reach them), the ratio of the second thickness e₂ to the first thickness e₁ is for example between 2 and 4.

In practice, the first thickness e₁ is, for example, between 3 and 7 nm. In an embodiment, this first thickness e is in the order of 4 nm.

The second thickness e₂ is, for example, between 8 and 17 nm. In an embodiment, this second thickness e₂ is in the order of 10 nm.

Here, the second thickness e₂ is therefore greater than the first thickness e₁. This means that a higher voltage will have to be applied to enable the information stored in the intermediate polarisation state associated with the second thickness e₂ (compared with the first thickness e₁) to be encoded.

The thickness ranges considered in an embodiment of the invention make it possible to enhance non-uniformities of the ferroelectric properties of the layer of ferroelectric material, so as to make it possible to store information on different intermediate polarisation states and to encode this information by distinguishing distinctly between these different states.

More particularly here, as is represented in FIG. 2, the second part 6 of the layer of ferroelectric material 5 comprises a first portion 6A and a second portion 6B.

The first portion 6A extends, at the bottom wall 52 of the cavity 50, as an extension of the first part 5A of the layer of ferroelectric material 5. For example, this first portion 6A has the same thickness e₁ as the first part 5A of the layer of ferroelectric material 5.

As visible in FIG. 2, the second portion 6B extends as a projection from the first portion 6A of the layer of ferroelectric material 5. In other words, the second portion 6B forms a protrusion of ferroelectric material on the first portion 6A of the layer of ferroelectric material 5.

Here, the second portion 6B has a trapezoidal (cross-sectional) shape, with a contact surface 6C with the first portion 6A of smaller dimension than the opposite (free) surface 6D. As is visible in FIG. 2, the second portion 6B is arranged so that this free surface 6D, corresponding to a free end of the second portion 6B, is positioned closer to the second layer 7 than to the first layer 2.

Beneficially according to an embodiment of the invention, the contact surface 6C represents, horizontally (in a plane parallel to the bottom wall 52 of the cavity 50), at least 75% of the total surface area S of the second part 6 of the layer of ferroelectric material 5. As is visible in FIG. 2, the total surface area S of the second part 6 of the layer of ferroelectric material 5 corresponds to the (horizontal) surface area of the first portion 6A of thickness e₁.

Thus, beneficially according to an embodiment of the invention, non-uniformities (associated with differences in thickness) in the layer of ferroelectric material are not manufacturing artefacts. The fact that the parts associated with the different thicknesses have large surface areas ensures that the polarisation states are quite distinct (and therefore that there is no overlap between the voltage ranges to be applied to deduce the different polarisation states).

As shown in FIG. 2, the ferroelectric storage device 1 also comprises the second layer 7. This second layer 7 is disposed on the ferroelectric material layer 5. The first part 5A and the second part 6 are therefore positioned between the first layer 2 and the second layer 7.

This second layer 7 comprises, for example, a conductive material. This is especially a metal material.

According to a first example (not represented), the second layer comprises a single layer. The conductive material of this single layer comprises, for example, titanium nitride TiN. Still alternatively, the conductive material may be tantalum nitride TaN or tungsten W. Alternatively, other conductive materials may be used (and in particular metal nitride more generally).

As is visible in FIG. 2, the second layer 7 is herein in the form of a two-layer structure. It comprises a first sub-layer 70 and a second sub-layer 72.

The second sub-layer 72 of the second layer 7 is disposed on the first sub-layer 70 associated therewith.

The second sub-layer 72 is formed of a conductive material comprising a transition metal. This conductive material is, for example, titanium nitride TiN. Alternatively, it may be other conductive materials such as tantalum nitride TaN or tungsten W.

The second sub-layer 72 has a thickness of between 10 and 200 nm.

This second sub-layer 72 acts both as a protective layer and as a contact layer for electrically connecting the device 1 to its electronic control and read circuit.

The first sub-layer 70 is disposed on the layer of ferroelectric material 5. It is in direct contact with the layer of ferroelectric material 5. In other words, the first sub-layer 70 of the second layer 7 extends between the second sub-layer 72 and the layer of ferroelectric material 5.

The second sub-layer 72 comprises a metal conductive material. In an embodiment, it comprises titanium Ti or tantalum Ta.

For example, when the second sub-layer 72 comprises titanium nitride, the first sub-layer 70 is formed of a conductive material such as titanium Ti.

Alternatively, when the second sub-layer 72 comprises tantalum nitride, the first sub-layer 70 is formed of a conductive material such as tantalum Ta.

Still alternatively, when the second sub-layer 72 comprises tungsten, the first sub-layer 70 is formed of a conductive material selected from titanium Ti or tantalum Ta.

Herein, the thickness of the first sub-layer 70 is between 3 and 20 nm.

In practice, in the case of an OxRAM (Oxide Resistive RAM) type memory, when this two-layer structure is used for the second layer 7, the first sub-layer 70 also has the feature of being a layer which will allow the creation of oxygen vacancies in the layer of ferroelectric material 5 (when this first sub-layer 70 is in contact with the layer of ferroelectric material 5). In this case, the first sub-layer 70 comprises a conductive material selected from titanium Ti or tantalum Ta, and the second sub-layer 72 comprises a titanium nitride TiN or a tantalum nitride TaN (so as to form a protective layer). The creation of these oxygen vacancies then improves performance of the ferroelectric storage device by facilitating oxygen exchanges with the layer of ferroelectric material.

In the case of a memory of the FeRAM type, the second layer 7 comprises, for example, a metal nitride or a metal which does not oxidise (such as tungsten W or ruthenium Ru).

In the case of an FTJ type memory, the structure used is that of a FeRAM type memory with the introduction of a layer comprising a dielectric material between the layer of ferroelectric material 5 and the second layer 7. The dielectric material is, for example, a dielectric oxide such as aluminium oxide Al₂O₃ or silicon dioxide SiO₂.

Alternatively, the second layer may comprise a semiconductor material. This semiconductor material comprises silicon, for example.

Beneficially according to an embodiment of the invention, the ferroelectric storage device comprises a layer of ferroelectric material of variable thickness. This variability in thickness results in non-uniformity in the ferroelectric properties of the ferroelectric storage device. This non-uniformity of properties especially makes it possible to increase differences between the voltage ranges to be applied to encode information in the different intermediate polarisation states.

In other words, by virtue of the non-uniformity created in the layer of ferroelectric material (due to thickness variability), differences between the intermediate polarisation states are created.

Alternatively, the layer of ferroelectric material may comprise more than two distinct thicknesses. This can especially be a continuous variation in thickness.

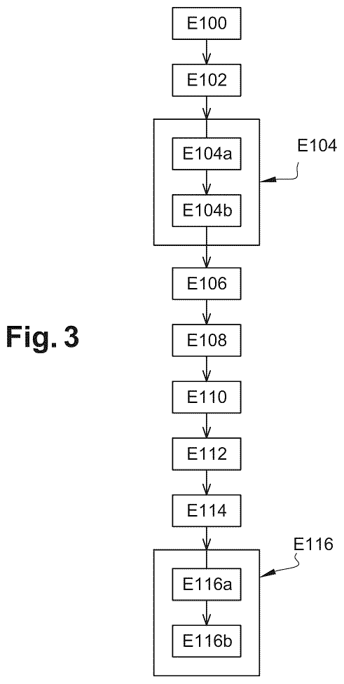

This invention also relates to a method for manufacturing a ferroelectric storage device 1. FIGS. 3 to 11 relate to this manufacturing method.

FIG. 3 represents, in the form of a flow chart, an example of the manufacturing method according to one exemplary embodiment.

As is visible in this FIG. 3, the manufacturing method comprises first of all a step E100 of providing a support layer 10 on which the ferroelectric storage device 1 will be formed. In practice, this support layer 10 is provided with at least one logic component associated with a metal interconnection element (not represented) for connecting the ferroelectric storage device 1 to lower metal levels.

The manufacturing method then continues in step E102, during which the cavity 50 (in which the ferroelectric storage device 1 will be formed) is formed. FIG. 4 illustrates this step E102.

In practice, this step E102 is implemented by anisotropic etching to form the bottom wall 52 and the side wall 55 of the cavity 50. This is for example dry chemical etching.

As described previously, the side wall 55 of the cavity 50 is made in such a way as to form the tilt angle α relative to the axis z parallel to a direction normal to the bottom wall 52. The side wall 55 therefore forms a non-zero tilt angle α relative to an axis z, corresponding to a direction normal to the bottom wall 52.

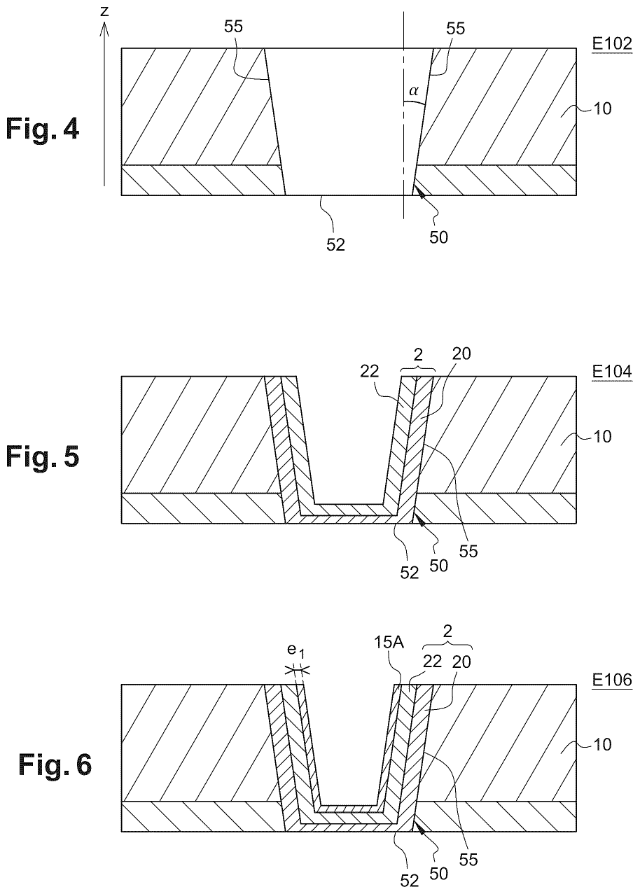

As is visible in FIG. 3, the manufacturing method continues with step E104 of depositing the first layer 2. FIG. 5 illustrates this step E104.

This first layer 2 is deposited in the cavity 50. More particularly, the first layer 2 is deposited along the bottom wall 52 and the side wall 55 of the cavity 50. The first layer 2 therefore lines and embraces the shape of the cavity 50.

Depositing the first layer 2 is herein conformally made. In this description, by “conformal deposition”, it is meant a deposition implemented in such a way that the layer has a substantially constant thickness at any point. In this description, by “substantially constant”, it is meant a thickness that does not vary by more than 20%, for example by more than 10%, and such as by more than 5%. For example, the first layer 2 can be formed by an Atomic Layer Deposition (ALD) method.

As previously indicated, the first layer 2 herein comprises a first sub-layer 20 and a second sub-layer 22.

Step E104 of depositing the first layer 2 therefore comprises two sub-steps: a first sub-step E104a of depositing the first sub-layer 20 and a second sub-step E104b of depositing the second sub-layer 22.

The first sub-layer 20 is therefore first deposited, conformally, in the cavity 50 (step E104a). In practice, the first sub-layer 20 is formed, for example, by an atomic layer deposition (or ALD) method or by chemical vapour deposition.

Alternatively, the first sub-layer 20 can be formed by sputtering in a vacuum deposition chamber. In the case where the first sub-layer 20 is formed of titanium nitride, this is a reactive sputtering process.

Then, the second sub-layer 22 of the first layer 2 is conformally deposited onto the first sub-layer 20 (step E104b). The second sub-layer 22 is formed, for example, by sputtering in a vacuum deposition chamber. In practice, the second sublayer 22 of the first layer 2 is formed in the same deposition chamber as the first sublayer 20 of the first layer 2.

In the case where the second sub-layer 22 is formed of titanium nitride, this is a reactive sputtering process.

The manufacturing method then continues with the step E106 of depositing a first layer of ferroelectric material 15A onto the first layer 2. More particularly, the first layer of ferroelectric material 15A is deposited onto the second sub-layer 22 of the first layer 2. This step E106 is represented in FIG. 6.

It is a conformal deposition of the first layer of ferroelectric material 15A onto the first layer 2.

Herein, for example, deposition step E106 is carried out in such a way that the first layer of ferroelectric material 15A has a thickness e₁.

In practice, the first layer of ferroelectric material 15A is deposited by an atomic layer deposition (or ALD) method.

Alternatively, the first layer of ferroelectric material may be deposited by sputtering. Still alternatively, the first layer of ferroelectric material may be deposited by a Physical Vapour Deposition (PVD) method. Still alternatively, the first layer of ferroelectric material can be deposited by an Ion Beam Deposition (IBD) method.

The method then continues, in step E108, with depositing an intermediate layer 17. This intermediate layer 17 is formed on the first layer of ferroelectric material 15A. This step E108 is represented in FIG. 7.

It is a conformal deposition of the intermediate layer 17 onto the first layer of ferroelectric material 15A. The intermediate layer 17 is therefore deposited uniformly (on the first layer of ferroelectric material 15A) along the side wall 55 and the bottom wall 52 of the cavity 50.

As shown in FIG. 7, the intermediate layer 17 comprises a first part 17A extending along the bottom wall 52 of the cavity 50 and a second part 17B extending along the side wall 55 of the cavity 50.

The intermediate layer 17 herein comprises, for example, a nitride or an oxide. For example, it is silicon nitride SiN or silicon carbonitride SiCN. Alternatively, the intermediate layer may comprise silicon dioxide SiO₂.

In practice, the intermediate layer 17 is deposited by an atomic layer deposition (ALD) method.

Alternatively, the intermediate layer can be deposited by sputtering. Still alternatively, the intermediate layer can be deposited by a physical vapour deposition (PVD) method. Still alternatively, the intermediate layer can be deposited by an Ion Beam Deposition (IBD) method.

Still alternatively, the intermediate layer can be formed according to a non-conformal deposition.

The thickness of the intermediate layer 17 is for example associated with the width I (illustrated in FIG. 7) of the first portion 6A of the first layer of ferroelectric material 15A. More particularly, the thickness of the intermediate layer 17 is herein less than 10% of the width I of the first portion 6A. In an embodiment, the thickness of the intermediate layer 17 is less than 7.5% of the width I of the first portion 6A.

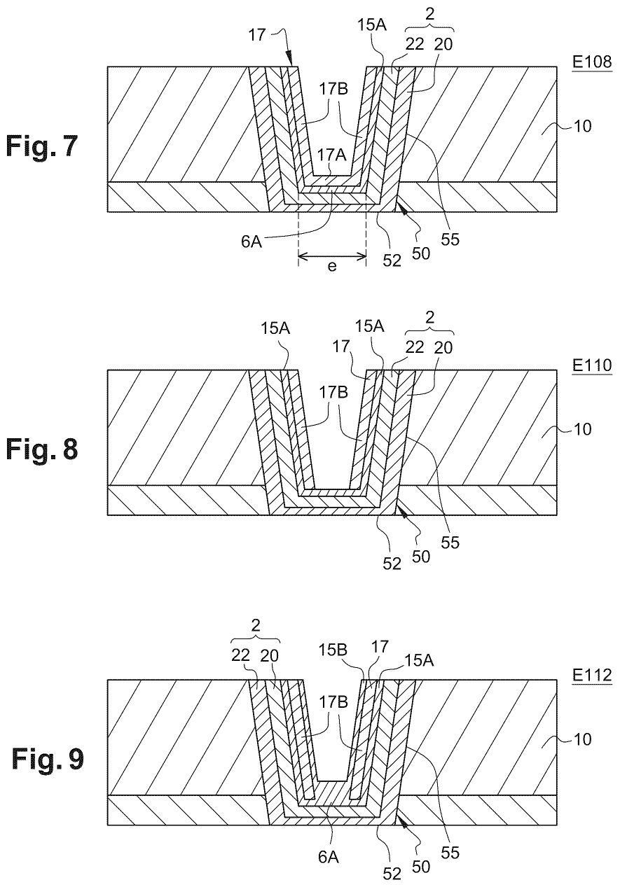

As shown in FIG. 3, the method continues with a step E110 of removing the first horizontal part 17A of the intermediate layer 17 so as to expose a part of the first layer of ferroelectric material 15A. This step E110 is represented in FIG. 8.

More particularly herein, the removal step E110 is intended to remove the portion of the intermediate layer 17 deposited at the bottom wall 52 of the cavity 50. The part of the first layer of ferroelectric material 15A exposed is therefore located at the bottom wall 52. In other words, at the end of the removal step E110, the intermediate layer 17 comprises a remaining part present at the side wall 55. This remaining part corresponds to the second part 17B of the intermediate layer 17 previously introduced.

In practice, this removal step E110 is carried out by anisotropic etching. This anisotropic etching therefore makes it possible to remove only the first part 17A of the intermediate layer 17.

This anisotropic etching is, for example, plasma etching. Alternatively, the anisotropic etching can be a Reactive Ion Etching (RIE).

At the end of step E110, along the bottom wall 52, the first portion 6A of the first layer of ferroelectric material 15A is therefore exposed. In other words, at the end of step E110, along the bottom wall 52 of the cavity 50, the first layer of ferroelectric material 15A is the last layer deposited. On the other hand, along the side wall 55 of the cavity, the intermediate layer 17 (and more particularly the second part 17B of the intermediate layer 17) is the last layer formed.

The manufacturing method then comprises a step E112 of depositing a second layer of ferroelectric material 15B. More particularly, this second layer of ferroelectric material 15B is formed on the second part 17B of the intermediate layer 17 and on the exposed part of the first layer of ferroelectric material 15A. In other words, the second layer of ferroelectric material 15B is formed on the second part 17B of the intermediate layer 17 and on the first portion 6A of the first layer of ferroelectric material 15A formed at the bottom wall 52. This step E112 is represented in FIG. 9.

It is a conformal deposition of the second layer of ferroelectric material 15B onto the second part 17B of the intermediate layer 17 and onto the first portion 6A of the first layer of ferroelectric material 15A.

Here, for example, deposition step E112 is implemented in such a way that the second layer of ferroelectric material 15B has a thickness e₃. This thickness e₃ is such that, at the bottom wall 52 of the cavity 50, the total thickness of ferroelectric material is of the order of the second thickness e₂.

In practice, the second layer of ferroelectric material 15B is deposited by an atomic layer deposition (ALD) method.

Alternatively, the second layer of ferroelectric material may be deposited by sputtering. Still alternatively, the second layer of ferroelectric material may be deposited by a physical vapour deposition (PVD) method. Still alternatively, the second layer of ferroelectric material can be deposited by an Ion Beam Deposition (IBD) method.

The second layer of ferroelectric material is, for example, herein formed of the same material as the first layer of ferroelectric material.

As is visible in FIG. 9, the intermediate layer 17 acts as a “spacer” between the first layer of ferroelectric material 15A and the second layer of ferroelectric material 15B.

As is visible in FIG. 3, the method for manufacturing continues with a step E114 (represented in FIG. 10). During this step, the second part 17B of the intermediate layer 17 is removed from the stack.

This step is specifically aimed at removing the remaining part of the intermediate layer 17. As in step E112 described previously, the second layer of ferroelectric material 15B has been partly deposited onto the second part 17B of the intermediate layer 17, step E114 of removing this second part 17B of the intermediate layer 17 also results in removing this part of the second layer of ferroelectric material 15B positioned on the second part 17B of the intermediate layer 17.

In other words, during this removal step E114, everything above the second part 17B of the intermediate layer 17 is removed at the same time as this second part 17B.

In practice, this removal step E114 is carried out by isotropic etching. For example, it is herein wet chemical etching. This etching is implemented with hot orthophosphoric acid, for example.

Thus, at the end of step E114, the intermediate layer 17 has been completely removed from the stack. With respect to the ferroelectric material, a single layer of ferroelectric material 5 is formed from the first layer of ferroelectric material 15A and the part of the second layer of ferroelectric material 15B deposited at the bottom wall 52 of the cavity 50. The part of the first layer of ferroelectric material 15A extending along the side wall 55 of the cavity 50 corresponds to the first part 5A of the ferroelectric storage device 1 previously introduced. The first portion 6A of the first layer of ferroelectric material 15A extending along the bottom wall 52 of the cavity, as well as the part of the second layer of ferroelectric material 15B deposited at the bottom wall 52 of the cavity 50 in turn form the second part 6 of the ferroelectric storage device 1 previously introduced.

This step E114 corresponds in fact to a so-called “lift-off” process which aims to specifically remove the second part 17B of the intermediate layer 17 so as to obtain a specific shape for the layer of ferroelectric material 5 obtained (herein with a projecting portion formed on the first portion 6A of the first layer of ferroelectric material 15A). The intermediate layer 17 thus herein forms here a sacrificial layer which makes it possible, by virtue of the manufacturing method according to an embodiment of the invention, to obtain a layer of ferroelectric material with a desired shape and variable thickness using only (in this manufacturing method) conformal depositions for the different layers involved.

In addition, the condition on the thickness of the intermediate layer mentioned previously makes it possible to ensure significant surface areas associated with each part of the layer of ferroelectric material of different thicknesses. This ensures very distinct polarisation states (and therefore no overlap between the voltage ranges to be applied to deduce the different polarisation states).

As is represented in FIG. 3, the manufacturing method ends with step E116. During this step, illustrated in FIG. 11, the second layer 7 is formed.

The second layer 7 is formed on the layer of ferroelectric material 5 obtained at the end of step E114.

Depositing the second layer 7 is herein conformally made.

As previously indicated, the second layer 7 can herein comprise a first sub-layer 70 and a second sub-layer 72.

Step E116 of depositing the second layer 7 therefore comprises two sub-steps: a first sub-step E116a of depositing the first sub-layer 70 and a second sub-step 116b of depositing the second sub-layer 72.

The first sub-layer 70 is therefore first deposited, conformally, onto the layer of ferroelectric material 5 (step E116a). In practice, the first sub-layer 70 is formed, for example, by sputtering in a vacuum deposition chamber. In the case where the first sub-layer 70 is formed of titanium nitride, this is a reactive sputtering process.

Alternatively, the first sub-layer can be formed by chemical vapour deposition.

Then, the second sub-layer 72 of the second layer 7 is deposited, conformally, onto the first sub-layer 70 (step E116b). As is visible in FIG. 11, the second sub-layer 72 is formed so as to fill all the remaining space in the cavity 50. Therefore, it achieves a ferroelectric storage device 1 completely integrated into the cavity 50 and without any projection or recess formed relative to the surface of the support layer 10. The assembly formed by the support layer 10 into which the ferroelectric storage device 1 is integrated therefore has a uniform surface.

In practice, the second sub-layer 72 is formed, for example, by sputtering in a vacuum deposition chamber. In practice, the second sub-layer 72 of the second layer 7 is formed in the same deposition chamber as the first sub-layer 70 of the second layer 7.

In the case where the second sub-layer 72 is made of titanium nitride, this is a reactive sputtering process.

In practice, although this is not visible in the appended figures, it is not excluded that the different layers of the ferroelectric storage device 1 are also deposited onto the front face (free surface opposite to the bottom wall 52) of the support layer 10. Thus, optionally, in order to ensure flatness and uniformity of the ferroelectric storage device 1 (and in particular of the free surface of the device 1), there can be provided a planarisation step, after step E116. This planarisation step is implemented, for example, by Chemical Mechanical Polishing (CMP). Any other adapted method can be used (especially masking methods).

This planarisation step is particularly beneficial because, by virtue of the uniformity of the surface of the device 1, it improves electrical performance of the ferroelectric storage device and ensures better quality interconnections.

Alternatively, an encapsulation step can be carried out after this planarisation step. Finally, a connection to the second layer 7 can be implemented.

Thus, at the end of the manufacturing method, the resulting ferroelectric storage device 1 comprises a layer of ferroelectric material with variable thickness. As previously indicated, the variability in thicknesses makes it possible to introduce non-uniformities in the ferroelectric properties of the layer of ferroelectric material. This non-uniformity of properties especially makes it possible to increase differences between the voltage ranges to be applied to encode the information in the different intermediate polarisation states.

This avoids overlap between the voltage ranges concerned and therefore enables unambiguous identification of the intermediate polarisation states related to the stored information.

In addition, the manufacturing method according to an embodiment of the invention makes it possible to obtain a three-dimensional architecture of the ferroelectric storage device 1. This makes it possible especially to increase the surface area of the capacity of the ferroelectric storage device 1.

The manufacturing method provided according to an embodiment of the invention is particularly simple to implement because it involves only conformal depositions to form each of the layers forming the ferroelectric storage device 1.

According to one alternative implementation of this embodiment, the manufacturing method may comprise, between the step E106 of depositing the first layer of ferroelectric material and the step E108 of depositing the intermediate layer, a step of implanting a doping element in the first layer of ferroelectric material formed in step E106. This step thus enables the layer of ferroelectric material to be doped with the doping element.

In practice, the implantation step is implemented, for example, in a reactor different from the deposition chamber for the first layer and the first layer of ferroelectric material.

This is herein, for example, a step of ionically implanting silicon (which is the doping element) into the layer of ferroelectric material. Implantation doses are, for example, between 1.10¹⁴ cm⁻² and 1.10¹⁵ cm⁻². In an embodiment, the implantation dose is between 0.3·10¹⁵ cm⁻² and 1.10¹⁵ cm⁻².

According to another alternative embodiment, the manufacturing method can also comprise, after the step E114 of removing the second part of the intermediate layer and before the step of depositing the second layer, a step of implanting a doping element in the second portion 6B of the layer of ferroelectric material (obtained at the end of step E114). This step then enables the second portion 6B of the layer of ferroelectric material to be doped with the doping element.

Here, for example, it is a step of ionically implanting silicon (which is the doping element) into the second portion 6B of the layer of ferroelectric material. The implantation doses are, for example, between 1.10¹⁴ cm⁻² and 1.10¹⁵ cm⁻². In an embodiment, the implantation dose is between 0.3·10¹⁵ cm⁻² and 1.10¹⁵ cm⁻².

Thus, as an alternative, the layer of ferroelectric material may be completely or only partially doped with the doping element.

### Applications

The ferroelectric storage device according to an embodiment of the invention finds a favoured application within the scope of FeRAM-type resistive memories.

It also finds a particular application within the scope of transistors, for example of the FeMFET («Ferroelectric-metal field effect transistor») type.

The ferroelectric storage device according to an embodiment of the invention can also be used within the scope of ferroelectric tunnel junctions (FTJs). In this case, an additional layer is added between the layer of ferroelectric material and the second layer. This additional layer comprises a dielectric material. This dielectric material is for example an aluminium oxide Al₂O₃.

In some of the applications mentioned (e.g. FeRAM or FTJ type memories), the first layer forms a first electrode (e.g. a lower electrode), the second layer forms a second electrode (e.g. an upper electrode) and the layer of ferroelectric material forms a memory layer.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A method for manufacturing a ferroelectric storage device comprising:
providing a support layer;
depositing a first layer;
depositing a first layer of ferroelectric material, and then
depositing an intermediate layer onto the first layer of ferroelectric material, and then
removing a first part of the intermediate layer so as to expose a part of the first layer of ferroelectric material, and then
depositing a second layer of ferroelectric material onto the intermediate layer and onto the part exposed of the first layer of ferroelectric material, and then
removing a second part of the intermediate layer so as to form, from the first layer of ferroelectric material and a portion of the second layer of ferroelectric material, a layer of ferroelectric material comprising a first part having a first thickness and a second part having a second thickness, the first thickness and the second thickness being distinct, and
depositing a second layer, the layer of ferroelectric material extending between the first layer and the second layer.

2. The manufacturing method according to claim 1, wherein depositing the first layer of ferroelectric material is conformally implemented.

3. The manufacturing method according to claim 1, wherein depositing the intermediate layer is conformally implemented.

4. The manufacturing method according to claim 1, wherein the intermediate layer comprises a nitride or an oxide.

5. The manufacturing method according to claim 1, wherein removing the first part of the intermediate layer is implemented by anisotropic etching.

6. The manufacturing method according to claim 1, wherein depositing the second layer of ferroelectric material is conformally implemented.

7. The manufacturing method according to claim 1, wherein removing the second part of the intermediate layer is implemented by isotropic etching.

8. The manufacturing method according to claim 1, wherein the layer of ferroelectric material comprises hafnium dioxide or hafnium dioxide doped with a doping element or an alloy HfₓZr₁₋ₓO₂, with 0<x<1.

9. The manufacturing method according to claim 1, comprising, prior to depositing the first layer, forming a cavity in the support layer, the cavity comprising a bottom wall and a side wall, the side wall forming a tilt angle relative to a direction normal to the bottom wall,
depositing the first layer, the layer of ferroelectric material and the second layer being implemented in the cavity formed,
the second part of the layer of ferroelectric material being positioned on the bottom wall of the cavity and the first part of the layer of ferroelectric material being positioned on the side wall of the cavity.

10. A ferroelectric storage device comprising a first layer, a second layer and a layer of ferroelectric material which extends between the first layer and the second layer, the ferroelectric storage device comprising a support layer which comprises a cavity, the cavity comprising a bottom wall and a side wall, the side wall forming a tilt angle relative to a direction normal to the bottom wall, the first layer, the layer of ferroelectric material and the second layer being located in the cavity, the layer of ferroelectric material comprising a first part having a first thickness and a second part having a second thickness, the first thickness and the second thickness being distinct, the first part and the second part of the layer of ferroelectric material being positioned between the first layer and the second layer, the second part of the layer of ferroelectric material comprising a first portion extending as an extension of the first part and a second portion extending as a projection from the first portion of the second part of the layer of ferroelectric material, the second portion being arranged so that a free end of this second portion is positioned closer to the second layer than to the first layer.
